(19) United States
(12) Patent Application Publication
(10) Pub. No.: US 2025/0126866 A1
(43) Pub. Date: Apr. 17, 2025

(54) SEMICONDUCTOR THIN FILM AND METHOD FOR PREPARING THE SAME

(71) Applicant: ENKRIS SEMICONDUCTOR, INC., Suzhou (CN)

(72) Inventor: Kai CHENG, Suzhou (CN)

(73) Assignee: ENKRIS SEMICONDUCTOR, INC., Suzhou (CN)

(21) Appl. No.: 18/915,715

(22) Filed: Oct. 15, 2024

(30) Foreign Application Priority Data
Oct. 16, 2023 (CN) 202311338765.1

(51) Int. Cl. H01L 29/20; H01L 21/02; H01L 21/311

(52) U.S. Cl. CPC H10D 62/8503; H01L 21/0254; H01L 21/31111; H01L 21/31144

(57) ABSTRACT

A method for preparing a semiconductor thin film includes: providing a substrate; patterning the substrate, the substrate, after being patterned, having a first groove separated from each other and a growth region surrounding the first groove; preparing a semiconductor thin film on the growth region, the semiconductor thin film being provided with a hollowed-out structure corresponding to a position of the first groove; with the semiconductor thin film used as a mask, etching, through the hollowed-out structure, the first groove to form a second groove by wet etching. An orthographic projection area, on a plane of the substrate, of the second groove is greater than an orthographic projection area, on the plane of the substrate, of the hollowed-out structure.

### CROSS-REFERENCE TO RELATED APPLICATIONS

The present disclosure claims priority to Chinese Patent Application No. 202311338765.1, filed on Oct. 16, 2023, which is hereby incorporated by reference in its entirety.

### TECHNICAL FIELD

The present disclosure relates to the technical field of semiconductor technologies, and in particular, to a semiconductor thin film and a method for preparing the same.

### BACKGROUND

Semiconductor thin films are prepared on the basis of heteroepitaxial technologies such as Metal-Organic Chemical Vapor Deposition (MOCVD), due to a large lattice mismatch and thermal mismatch between a heteroepitaxial substrate (such as sapphire, silicon, etc.) used in heterogeneous epitaxy and a semiconductor thin film, resulting in a tensile stress between the semiconductor thin film and the heterogeneous substrate, cracks occur when the semiconductor thin film is prepared to a certain thickness, which seriously affects the quality of the semiconductor thin film.

The price of AlN self-supporting substrates is very expensive. At present, AlN single crystal thin films are mostly obtained on substrates such as sapphire, silicon or SiC by Metal-Organic Chemical Vapor Deposition (MOCVD), Molecular Beam Epitaxy (MBE) or Hydride Vapor Phase Epitaxy (HVPE). Growing an AlN thin film on a silicon substrate is a huge challenge. On the one hand, due to a large lattice mismatch between a silicon substrate and an AlN material, a large amount of penetrating dislocations are generated in the production process, and the penetrating dislocations cause poor material quality, limiting performances of various devices; in addition, lattice mismatch also leads to huge tensile stress generated in a growth process of AlN, which eventually leads to cracks in the epitaxial film and makes it unusable; on the other hand, due to the large thermal mismatch between AlN and silicon substrate materials, that is, a difference in thermal expansion coefficients, the AlN epitaxial film grown at high temperature will produce additional tensile stress in cooling process, leading to cracks in the epitaxial film and making it unusable. In a word, the high dislocation density and cracks caused by tensile stress greatly limit the device application of the heteroepitaxial AlN thin film materials.

### SUMMARY

The main purpose of the present disclosure is to provide a semiconductor thin film and a method for preparing the same, to solve the problems of large mismatch and large tensile stress between a semiconductor thin film and a heterogeneous substrate, which makes it difficult to prepare a high-quality self-supporting semiconductor thin film in the conventional technology.

According to one aspect, embodiments of the present disclosure provide a method for preparing a semiconductor thin film, including: providing a substrate; patterning the substrate, the substrate, after being patterned, having a first groove separated from each other and a growth region surrounding the first groove; preparing a semiconductor thin film on the growth region, the semiconductor thin film being provided with a hollowed-out structure corresponding to a position of the first groove; with the semiconductor thin film used as a mask, etching, through the hollowed-out structure, the first groove to form a second groove by wet etching, where an orthographic projection area, on a plane of the substrate, of the second groove is greater than an orthographic projection area, on the plane of the substrate, of the hollowed-out structure.

As an optional embodiment, the substrate includes a plurality of first grooves, and the plurality of first grooves are etched to be communicated together to form the second groove, the semiconductor thin film with the hollowed-out structure is suspended on the second groove, the hollowed-out structure includes a plurality of through holes, and the plurality of through holes are communicated with the second groove.

As an optional embodiment, the plurality of through holes of the hollowed-out structure have a same size and are uniformly distributed.

As an optional embodiment, an area density, on the substrate, of the first groove is uniform, and an area density, on the semiconductor thin film, of the hollowed-out structure is uniform.

As an optional embodiment, the substrate includes a plurality of substrate sub-regions, area densities of the first groove in two or more substrate sub-regions are different, and area densities of the hollowed-out structure corresponding to two or more substrate sub-regions are different.

As an optional embodiment, the substrate includes a plurality of substrate sub-regions, first grooves in each of the plurality of substrate sub-regions have a same size, and first grooves in two or more substrate sub-regions have different sizes.

As an optional embodiment, the substrate includes an edge region and a central region, and an area density of the first groove in the edge region is greater than an area density of the first groove in the central region.

As an optional embodiment, the substrate includes a plurality of second grooves, and two or more second grooves have different sizes.

As an optional embodiment, a material of the semiconductor thin film includes one of or a combination of AlN, GaN, InN, AlScN, AlGaN or AlInGaN.

As an optional embodiment, the semiconductor thin film includes a first semiconductor thin film and a second semiconductor thin film formed on the first semiconductor thin film, where the preparing a semiconductor thin film on the growth region, includes: preparing the first semiconductor thin film on the growth region, where the hollowed-out structure is formed at a position, corresponding to the first groove, of the first semiconductor thin film; with the first semiconductor thin film used as a mask, etching, through the hollowed-out structure, the first groove to form a second groove by wet etching; continually growing the second semiconductor thin film on the first semiconductor thin film with the hollowed-out structure, and the hollowed-out structure extending from the first semiconductor thin film partially penetrates or completely penetrates through the second semiconductor thin film.

As an optional embodiment, a material of the second semiconductor thin film and a material of the first semiconductor thin film are different.

As an optional embodiment, a material of the first semiconductor thin film is AlN, a material of the second semiconductor thin film is AlScN, and a doping method of a Sc component in the second semiconductor thin film includes uniform doping, modulation doping or periodic doping.

As an optional embodiment, the substrate includes a silicon-on-insulator (SOI) substrate, the silicon-on-insulator substrate includes a supporting layer, a bonding layer and an active silicon layer which are stacked sequentially, and the first groove is disposed in the active silicon layer.

As an optional embodiment, the substrate includes a Qromis Substrate Technology (QST) engineered substrate, the QST engineered substrate includes a polycrystalline ceramic core, a barrier layer, a bonding layer and an active silicon layer which are stacked sequentially, and the first groove is disposed in the active silicon layer.

As an optional embodiment, a shape of a horizontal cross-section of the first groove includes any one of a triangle, a circle, an ellipse, a polygon, a strip shape, or a mesh shape, and the cross-section is parallel to the substrate.

As an optional embodiment, a growth method of the semiconductor thin film includes an in-situ growth method, an atomic layer deposition method, a chemical vapor deposition method, a molecular beam epitaxial growth method, a plasma enhanced chemical vapor deposition method, a low-pressure chemical evaporation deposition method, a metal organic compound chemical vapor deposition method, or a combination thereof.

As an optional embodiment, a material of the substrate includes any one of sapphire, silicon or silicon carbide.

According to another aspect, embodiments of the present disclosure provide a semiconductor thin film, the semiconductor thin film is prepared by any one of the methods described above.

According to another aspect, the semiconductor thin film is applied to the fields of Acoustic Resonator (AR), Light Emitting Diode (LED), High Electron Mobility Transistor (HEMT), High Mobility Diode (HMD), Metal-Oxide-Semiconductor Field Effect Transistor (MOSFET), Ultraviolet Light Emitting Diode (UV-LED), photoelectric detector, hydrogen generator or solar cell.

As an optional embodiment, a material of the semiconductor thin film includes one of or a combination of AlN, GaN, In, AlScN, AlGaN or AlInGaN.

The present disclosure provides the semiconductor thin film and the method for preparing the same. The semiconductor thin film with a hollowed-out structure is formed by using a patterned substrate, by using the semiconductor thin film as a mask, the substrate is further removed by wet etching, the first groove is etched to form a second groove, an orthographic projection area, on a plane of the substrate, of the second groove is greater than an orthographic projection area, on the plane of the substrate, of the hollowed-out structure, and in the growth process, because the first groove is deeply etched to form a second groove, part of the semiconductor thin film is suspended on the second groove, the suspended structure can relax tensile stress to inhibit the generation of cracks; in addition, because the substrate is further removed, the number of dislocations formed at the interface between the substrate and the semiconductor thin film is further reduced due to a reduction of the contact area between the substrate and the semiconductor thin film, and the dislocations may further be annihilated in the growth process of the semiconductor thin film, so as to finally obtain the high quality semiconductor thin film with no cracks and a low dislocation density.

### BRIEF DESCRIPTION OF THE DRAWINGS

FIG. 1 is a schematic flowchart of a method for preparing a semiconductor thin film according to Embodiment 1 of the present disclosure.

FIG. 2a to FIG. 2d are schematic structural diagrams of a semiconductor thin film according to Embodiment 1 of the present disclosure.

FIG. 3 is a schematic structural diagram of a semiconductor thin film according to Embodiment 2 of the present disclosure.

FIG. 4a to FIG. 4d are schematic structural diagrams of a semiconductor thin film according to Embodiment 3 of the present disclosure.

FIG. 5 is a schematic top view of a substrate sub-region according to Embodiment 3 of the present disclosure.

FIG. 6 is a schematic structural diagram of a semiconductor thin film according to Embodiment 4 of the present disclosure.

FIG. 7a to FIG. 7c are schematic structural diagrams of a semiconductor thin film according to Embodiment 5 of the present disclosure.

### DETAILED DESCRIPTION OF THE EMBODIMENTS

The following clearly and completely describes the technical solutions in the embodiments of the present disclosure with reference to the accompanying drawings in the embodiments of the present disclosure. Apparently, the described embodiments are a part rather than all of the embodiments of the present disclosure. All other embodiments obtained by a person of ordinary skill in the art based on the embodiments of the present disclosure without creative efforts shall fall within the protection scope of the present disclosure.

In order to solve the problems of large mismatch and large tensile stress between a semiconductor thin film and a heterogeneous substrate, which makes it difficult to prepare a high-quality self-supporting semiconductor thin film in the conventional technology, the present disclosure provides a semiconductor thin film and a method for preparing the same, the semiconductor thin film having a hollowed-out structure is formed by using a patterned substrate, by using the semiconductor thin film as a mask, the substrate is further removed by wet etching, the first groove is etched to form a second groove, an orthographic projection area, on a plane of the substrate, of the second groove is greater than an orthographic projection area, on the plane of the substrate, of the hollowed-out structure, and in the growth process, because the first groove is deeply etched, part of the semiconductor thin film is suspended on the second groove, the suspended structure can relax tensile stress to inhibit the generation of cracks; in addition, because the substrate is further removed, the number of dislocations formed at the interface between the substrate and the semiconductor thin film is further reduced due to a reduction of the contact interface between the substrate and the semiconductor thin film, and the dislocations may further be annihilated in the growth process of the semiconductor thin film, so as to finally obtain the high quality semiconductor thin film with no cracks and a low dislocation density.

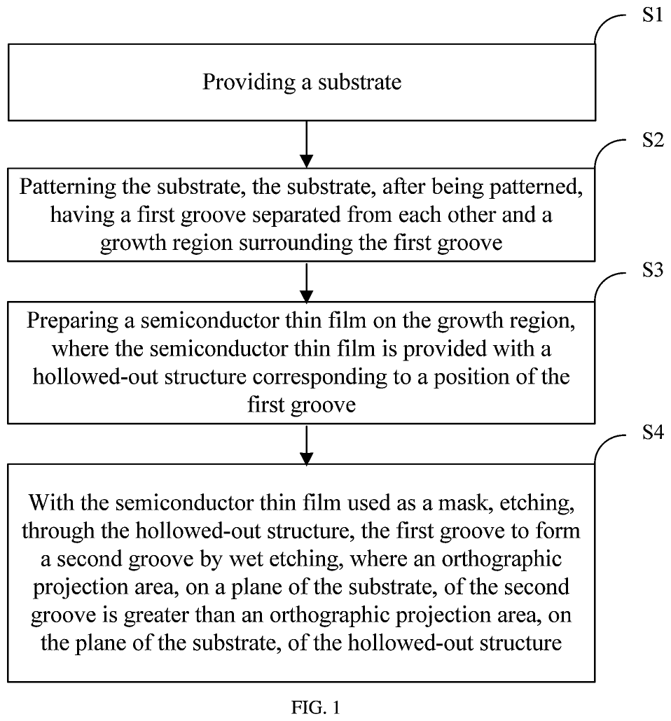

The following further illustrates the semiconductor thin film and the method for preparing the same mentioned in the present disclosure with reference to FIG. 1 to FIG. 7.

### Embodiment 1

FIG. 1 is a schematic flowchart of a method for preparing a semiconductor thin film according to Embodiment 1 of the present disclosure. As shown in FIG. 1, the method includes Step S1 to Step S4.

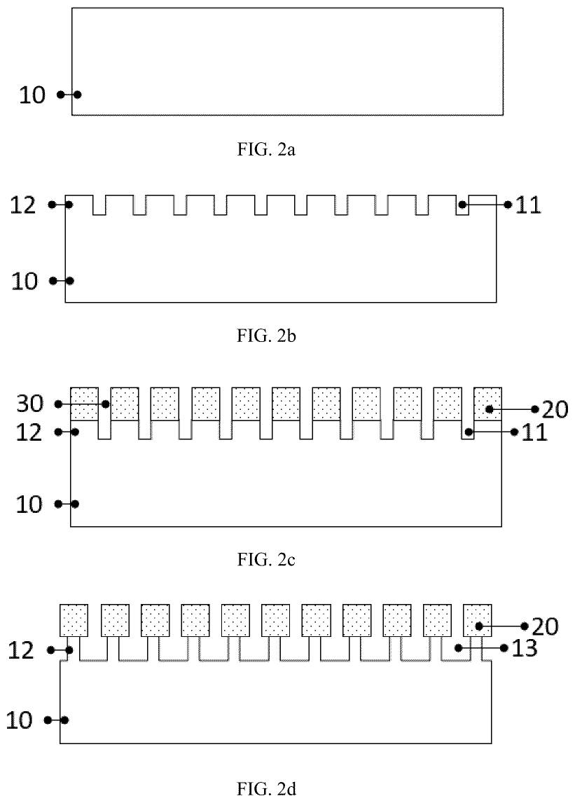

Step S1: as shown in FIG. 2a, providing a substrate 10.

Step S2: as shown in FIG. 2b, patterning the substrate 10, the substrate 10, after being patterned, having a first groove 11 separated from each other and a growth region 12 surrounding the first groove 11.

Step S3: as shown in FIG. 2c, preparing a semiconductor thin film 20 on the growth region 12, where the semiconductor thin film 20 is provided with a hollowed-out structure 30 corresponding to a position of the first groove 11.

Step S4: as shown in FIG. 2d, with the semiconductor thin film 20 used as a mask, etching, through the hollowed-out structure 30, the first groove 11 to form a second groove 13 by wet etching, where an orthographic projection area, on a plane of the substrate, of the second groove 13 is greater than an orthographic projection area, on the plane of the substrate 10, of the hollowed-out structure 30. That is, the semiconductor thin film 20 is partially suspended on the second groove 13, and the suspended semiconductor thin film 20 can further release the lattice mismatch stress.

In some embodiments, a material of the semiconductor thin film 20 is a hexagonal system semiconductor material, for example, it may be one of or a combination of AlN, GaN, InN, AlScN, AlGaN or AlInGaN. A growth of the semiconductor thin film 20 may be in-situ growth, or may be prepared by Atomic Layer Deposition (ALD), Chemical Vapor Deposition (CVD), Molecular Beam Epitaxy (MBE), Plasma Enhanced Chemical Vapor Deposition (PECVD), Low Pressure Chemical Evaporation Deposition (LPCVD), Metal-Organic Chemical Vapor Deposition (MOCVD), or a combination thereof. Unless specifically stated, the growth conditions of the semiconductor thin film 20 may be adjusted by a person skilled in the art or adjusted according to specific requirements.

In some embodiments, a material of the substrate 1 includes any one of sapphire, silicon or silicon carbide.

In some embodiments, the substrate 1 is a composite substrate, the composite substrate is a silicon-on-insulator (SOI) substrate, the silicon-on-insulator substrate includes a supporting layer, a bonding layer and an active silicon layer which are stacked sequentially, and the first groove is disposed in the active silicon layer.

In other embodiments, the composite substrate is a QST (Qromis Substrate Technology) engineered substrate, the QST engineered substrate includes a polycrystalline ceramic core, a barrier layer, a bonding layer and an active silicon layer which are stacked sequentially, and the first groove is disposed in the active silicon layer.

In some embodiments, a shape of a horizontal cross-section of the first groove 11 includes any one of a triangle, a circle, an ellipse, a polygon, a strip shape or a mesh shape, and the cross-section is parallel to the substrate 10.

The “area density” herein refers to a proportion of the total projected area of holes (including the first groove, the second groove, and the hollowed-out structure) in a top view direction in a unit area of the substrate or the semiconductor thin film.

In some embodiments, an area density, on the substrate 10, of the first groove 11 is uniform; because the hollowed-out structure 30 on the semiconductor thin film 20 corresponds to the first groove 11, a distribution of the first groove 11 determines a distribution of the hollowed-out structure 30 on the semiconductor thin film 20, when the area density, on the substrate 10, of the first groove 11 is uniform, the area density, on the semiconductor thin film 20, of the corresponding hollowed-out structure 30 is uniform. Optionally, the area density, on the substrate 10, of the first groove 11 is symmetrical and changes periodically. The distribution of the first grooves 11 on the substrate 10 plays a role in releasing the tensile stress and adjusting the uneven distribution of the stress between the semiconductor thin film 20 and the substrate 10 caused by lattice mismatch and thermal mismatch. In some embodiments, the area density, on the substrate 10, of the first groove 11 may be adjusted according to actual requirements, which is not limited in the present disclosure.

### Embodiment 2

FIG. 3 is a schematic structural diagram of a semiconductor thin film according to Embodiment 2 of the present disclosure. A method for preparing a semiconductor thin film according to Embodiment 2 is substantially the same as the method for preparing a semiconductor thin film according to Embodiment 1, specifically, step S1 to step S3 are the same, referring to FIG. 2a to FIG. 2c, differences are as follows.

Step S4: as shown in FIG. 3, with a first semiconductor thin film 20 used as a mask, through the hollowed-out structure 30, further removing the substrate 10 by wet etching, the first groove 11 being etched to form a second groove 13, where a plurality of first grooves 11 are etched to be communicated together to form the second groove 13, the semiconductor thin film 20 having the hollowed-out structure 30 is suspended on the second groove 13. The hollowed-out structure 30 includes a plurality of through holes, and the plurality of through holes are communicated with the second groove 13. In Embodiment 2, a plurality of first grooves 11 are etched to be communicated together to form the second groove 13, the semiconductor thin film 20 having the hollowed-out structure 30 is suspended on the second groove 13. In Embodiment 2, a size of the second groove 13 is further enlarged and the substrate 10 is further removed, an area of the semiconductor thin film 20 suspended on the second groove 13 increases, so a contact interface between the substrate 10 and the semiconductor thin film 20 is reduced and the number of dislocations formed at the interface between the substrate 10 and the semiconductor thin film 20 is further reduced, the dislocations may further be annihilated in the growth process of the semiconductor thin film 20, so as to finally obtain the high quality semiconductor thin film with no cracks, low dislocation density and well crystal surface state.

### Embodiment 3

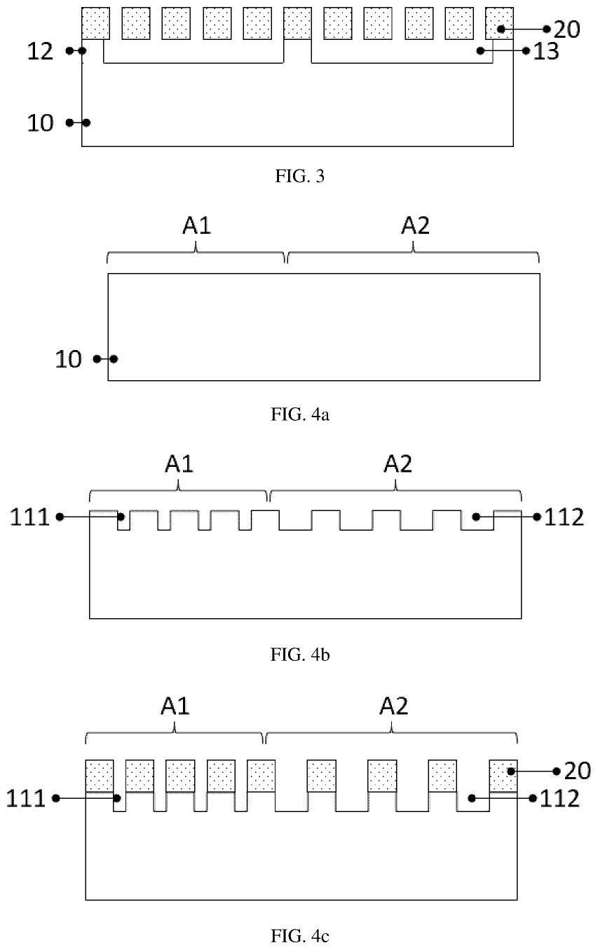

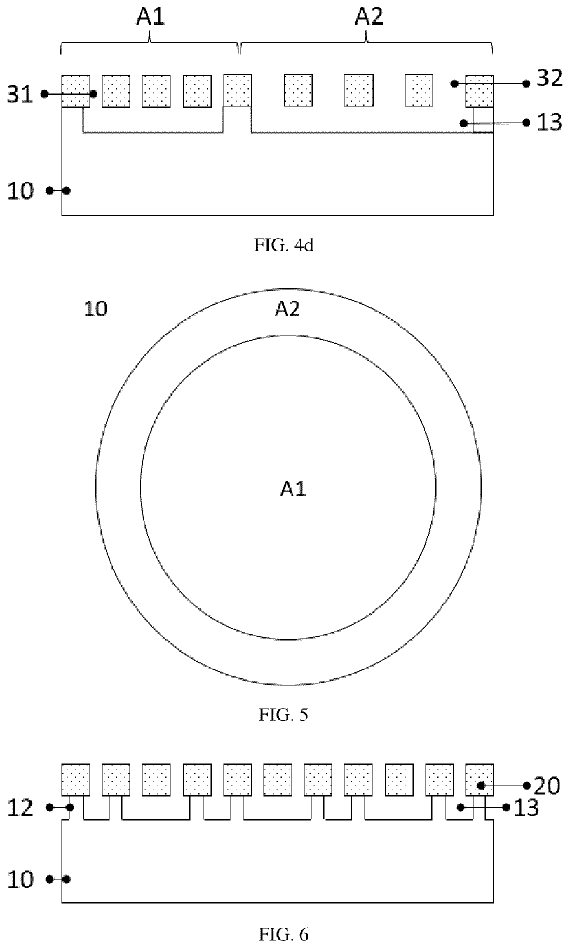

FIG. 4a to FIG. 4d are schematic structural diagrams of a semiconductor thin film according to Embodiment 3 of the present disclosure.

A method for preparing a semiconductor thin film according to Embodiment 3 is substantially the same as the method for preparing a semiconductor thin film according to Embodiment 1 and Embodiment 2, the only difference is that the substrate includes a plurality of substrate sub-regions, area densities of the first groove in two or more substrate sub-regions are different, and area densities of the hollowed-out structure corresponding to two or more substrate sub-regions are different.

The method for preparing the semiconductor thin film according to Embodiment 3 includes the following content.

Step S1: as shown in FIG. 4a, the substrate 10 includes a first substrate sub-region A1 and a second substrate sub-region A2.

Step S2: as shown in FIG. 4b, the substrate 10 is patterned, and the substrate 10, after being patterned, has a first groove 11 separated from each other and a growth region 12 surrounding the first groove 11, where an area density of the first groove 111 in the first substrate sub-region A1 is less than an area density of the first groove 112 in the second substrate sub-region A2. Optionally, first grooves 111 in the first substrate sub-region A1 have a same size and uniform distribution, and has a first size d1; first grooves 112 in the second substrate sub-region A2 have a same size and uniform distribution, and has a second size d2; and the first size d1 is smaller than the second size d2.

Step S3: as shown in FIG. 4c, the semiconductor thin film 20 is prepared on the growth region 12, and the semiconductor thin film 20 is provided with a hollowed-out structure 30 corresponding to a position of the first groove 11.

Step S4: as shown in FIG. 4d, with the semiconductor thin film 20 used as a mask, through the hollowed-out structure, the substrate 10 is further removed by wet etching, and the first groove 11 is continuously etched to form a second groove 13, where an orthographic projection area, on the plane of the substrate 10, of the second groove 13 is greater than an orthographic projection area, on the plane of the substrate 10, of the hollowed-out structure 30. That is, the semiconductor thin film 20 is partially suspended on the second groove 13, and the suspended semiconductor thin film 20 may further release the lattice mismatch stress. It can be seen from FIG. 4d that an area density of the hollowed-out structure 31 corresponding to the first substrate sub-region Al is less than an area density of the hollowed-out structure 32 corresponding to the second substrate sub-region A2, and the stress distribution at the interface may be further adjusted by adjusting the area density of the hollowed-out structure corresponding to different sub-regions.

The distribution of the first groove on the substrate plays a role in releasing tensile stress and adjusting the uneven distribution of stress between the semiconductor thin film and the substrate caused by lattice mismatch and thermal mismatch. In some embodiments, by dividing the substrate into the substrate sub-regions, the stress at the interface between the substrate and the semiconductor thin film is simply and efficiently adjusted. In some embodiments, the area density, on the substrate, of the first groove may be adjusted according to actual requirements, which is not limited in the present disclosure. It should be noted that sub-regions of the substrate 10 is not limited to two, and the number of the substrate sub-regions may be set according to actual requirements.

FIG. 5 is a schematic top view of a substrate sub-region according to Embodiment 3 of the present disclosure, in this embodiment, the first substrate sub-region A1 is a central region of the substrate 10, and the second substrate sub-region A2 is an edge region of the substrate 10. The edge region and central region are unevenly distributed during a growth of semiconductor film 20. The area density of the first groove in the edge region and the area density of the first groove in the central region may be adjusted according to actual requirements, optionally, the area density of the first groove in the edge region is greater than the area density of the first groove in the central region.

### Embodiment 4

FIG. 6 is a schematic structural diagram of a semiconductor thin film according to Embodiment 4 of the present disclosure. A method for preparing a semiconductor thin film according to Embodiment 4 is substantially the same as the method for preparing the semiconductor thin film according to Embodiment 1 to Embodiment 3, differences are only as follows.

Step S4: as shown in FIG. 6, with the semiconductor thin film 20 used as a mask, through the hollowed-out structure 30, a substrate 10 is further removed by wet etching, a first groove 11 is etched to form a second groove 13, and the substrate 10 includes a plurality of second grooves 13, where two or more second grooves have different size.

In this embodiment, the size of the second groove 13 is adjusted by adjusting the wet etching, in this embodiment, the second groove 13 may be formed by etching a single first groove, or may be formed by etching a plurality of first grooves to be communicated together, which is not limited in the present disclosure.

### Embodiment 5

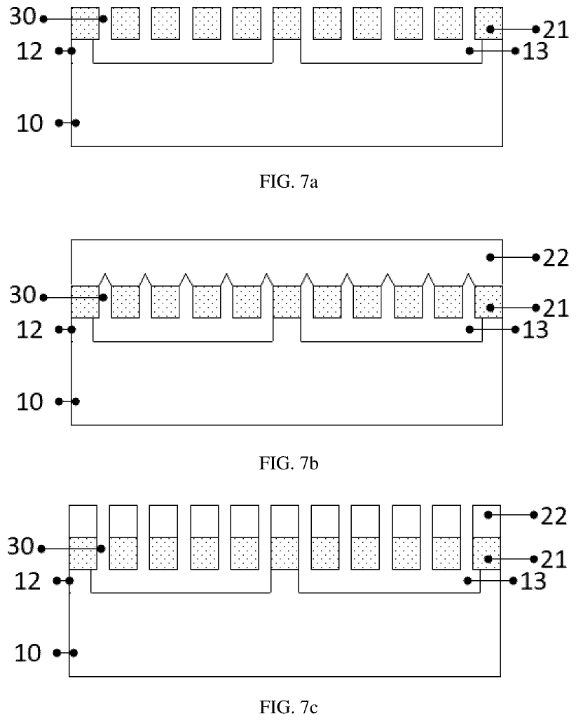

FIG. 7a to FIG. 7c are schematic structural diagrams of a semiconductor thin film according to Embodiment 5 of the present disclosure.

A method for preparing a semiconductor thin film according to Embodiment 5 is substantially the same as the method for preparing a semiconductor thin film according to Embodiment 1 to Embodiment 4, the only difference is that the semiconductor thin film includes a first semiconductor thin film and a second semiconductor thin film formed on the first semiconductor thin film, and the hollowed-out structure extending from the first semiconductor thin film partially penetrates or completely penetrates through the second semiconductor thin film.

In Embodiment 5, the preparing a semiconductor thin film on the growth region 12 including the following contents.

As shown in FIG. 7a, a first semiconductor thin film 21 is prepared on a growth area 12, and a hollowed-out structure 30 is formed at a position, corresponding to a first groove 11, of the first semiconductor thin film 21; with the first semiconductor thin film 21 used as a mask, through the hollowed-out structure 30, a substrate 10 is further removed by wet etching, and the first groove 11 is continuously etched to form a second groove 13.

As shown in FIG. 7b, a second semiconductor thin film 22 is continually grown on the first semiconductor thin film 21 having the hollowed-out structure 30, and the hollow structure 30 extending from the first semiconductor thin film 21 partially penetrates the second semiconductor thin film 22; as shown in FIG. 7c, the hollowed-out structure 30 extending from the first semiconductor thin film 21 completely penetrates through the second semiconductor thin film 22.

In some embodiments, a material of the second semiconductor thin film 22 is different from a material of the first semiconductor thin film 21. Optionally, the material of the first semiconductor thin film 21 is AlN, the material of the second semiconductor thin film 22 is AlScN, and a doping method of the Sc component in the second semiconductor thin film 22 includes uniform doping, modulation doping or periodic doping.

In this embodiment, the hollowed-out structure 30 in the present disclosure can reduce the tensile stress between the semiconductor thin film and the heterogeneous substrate caused by lattice mismatch and thermal mismatch, after the second groove 13 is formed by etching, the first semiconductor thin film 21 is suspended on the second groove 13, due to the contact area of the substrate 10 and the first semiconductor thin film 21 is greatly reduced, the tensile stress at the interface is greatly released; by continually growing the second semiconductor thin film 22 on the suspended first semiconductor thin film 21, defect merging may also be carried out during the process of growing the second semiconductor thin film 22, further reducing the defect density and obtaining the second semiconductor thin film 22 with a low defect density in an upper surface and a well crystal surface state, which is beneficial to further preparing a high quality nitride substrate material and a nitride semiconductor device with a certain thickness on the second semiconductor thin film 22.

The present disclosure also provides a semiconductor thin film, which is obtained according to the method for preparing the semiconductor thin film provided in Embodiment 1 to Embodiment 5, and the semiconductor thin film is applied to the fields of Acoustic Resonator (AR), Light Emitting Diode (LED), High Electron Mobility Transistor (HEMT), High Mobility Diode (HMD), MOSFET (Metal-Oxide-Semiconductor Field Effect Transistor), UV-LED (Ultraviolet Light Emitting Diode), photoelectric detector, hydrogen generator or solar cell.

The present disclosure provides a semiconductor thin film and a method for preparing the same, the semiconductor thin film having a hollowed-out structure is formed by using a patterned substrate, by using the semiconductor thin film as a mask, the substrate is further removed by wet etching, the first groove is etched to form a second groove, an orthographic projection area, on a plane of the substrate, of the second groove is greater than an orthographic projection area, on the plane of the substrate, of the hollowed-out structure, and in the growth process, because the first groove is deeply etched to form a second groove, part of the semiconductor thin film is suspended on the second groove, the suspended structure can relax tensile stress to inhibit the generation of cracks; in addition, because the substrate is further removed, the number of dislocations formed at the interface between the substrate and the semiconductor thin film is further reduced due to a reduction of the contact area between the substrate and the semiconductor thin film, and the dislocations may further be annihilated in the growth process of the semiconductor thin film, so as to finally obtain the high quality semiconductor thin film with no cracks and a low dislocation density. According to the technical solution of the present disclosure, not only the dislocation defect density and the tensile stress can be effectively reduced, but also the preparation process flow is simple, having a low cost, a well merging effect, low defect density and well material crystal quality, the preparation method is particularly suitable for large-scale industrial production.

According to the method for preparing the semiconductor thin film provided by the present disclosure, thick film materials with high growth rate and low dislocation density can be obtained, with low production cost, flexible growth condition and well reproducibility. In the process of stripping the semiconductor thin film from the substrate, it does not need complex and expensive laser lift-off equipment but only cheap chemical etching solution, so that the cost is low.

It should be understood that the term “including” and variations thereof used in the present disclosure are open-ended, i.e. “including but not limited to”. The term “an embodiment” means “at least one embodiment”; and the term “another embodiment” means “at least one additional embodiment”. In the specification, schematic representations of the above terms may not be directed to identical embodiments or examples. The specific features, structures, materials or characteristics described may be combined in a suitable manner in any one or more embodiments or examples. In addition, without contradicting each other, a person skilled in the art may combine and constitute different embodiments or examples described in this specification, and the features in different embodiments or examples.

The foregoing descriptions are merely preferred embodiments of the present disclosure, but are not intended to limit the protection scope of the present disclosure. Any modifications, equivalent replacements, etc. made within the spirit and principles of the present disclosure should be included in the protection scope of the present disclosure.

What is claimed is:

1. A method for preparing a semiconductor thin film, comprising:
providing a substrate;
patterning the substrate, the substrate, after being patterned, having a first groove separated from each other and a growth region surrounding the first groove;
preparing a semiconductor thin film on the growth region, the semiconductor thin film being provided with a hollowed-out structure corresponding to a position of the first groove; and
with the semiconductor thin film used as a mask, etching, through the hollowed-out structure, the first groove to form a second groove by wet etching, wherein an orthographic projection area, on a plane of the substrate, of the second groove is greater than an orthographic projection area, on the plane of the substrate, of the hollowed-out structure.

2. The method for preparing the semiconductor thin film according to claim 1, wherein the substrate comprises a plurality of first grooves, and the plurality of first grooves are etched to be communicated together to form the second groove, the semiconductor thin film with the hollowed-out structure is suspended on the second groove, the hollowed-out structure comprises a plurality of through holes, and the plurality of through holes are communicated with the second groove.

3. The method for preparing the semiconductor thin film according to claim 2, wherein the plurality of through holes of the hollowed-out structure have a same size and are uniformly distributed.

4. The method for preparing the semiconductor thin film according to claim 1, wherein an area density, on the substrate, of the first groove is uniform, and an area density, on the semiconductor thin film, of the hollowed-out structure is uniform.

5. The method for preparing the semiconductor thin film according to claim 1, wherein the substrate comprises a plurality of substrate sub-regions, area densities of the first groove in two or more substrate sub-regions are different, and area densities of the hollowed-out structure corresponding to the two or more substrate sub-regions are different.

6. The method for preparing the semiconductor thin film according to claim 1, wherein the substrate comprises a plurality of substrate sub-regions, first grooves in each of the plurality of substrate sub-regions have a same size, and first grooves in two or more substrate sub-regions have different sizes.

7. The method for preparing the semiconductor thin film according to claim 1, wherein the substrate comprises an edge region and a central region, and an area density of the first groove in the edge region is greater than an area density of the first groove in the central region.

8. The method for preparing the semiconductor thin film according to claim 1, wherein the substrate comprises a plurality of second grooves, and two or more second grooves have different sizes.

9. The method for preparing the semiconductor thin film according to claim 1, wherein a material of the semiconductor thin film comprises one of or a combination of AlN, GaN, InN, AlScN, AlGaN or AlInGaN.

10. The method for preparing the semiconductor thin film according to claim 1, wherein the semiconductor thin film comprises a first semiconductor thin film and a second semiconductor thin film formed on the first semiconductor thin film, the preparing the semiconductor thin film on the growth region, comprises:
preparing the first semiconductor thin film on the growth region, wherein the hollowed-out structure is formed at a position, corresponding to the first groove, of the first semiconductor thin film;
with the first semiconductor thin film used as a mask, etching, through the hollowed-out structure, the first groove to form a second groove by wet etching; and
continually growing the second semiconductor thin film on the first semiconductor thin film with the hollowed-out structure, and the hollowed-out structure extending from the first semiconductor thin film partially penetrates or completely penetrates through the second semiconductor thin film.

11. The method for preparing the semiconductor thin film according to claim 10, wherein a material of the second semiconductor thin film and a material of the first semiconductor thin film are different.

12. The method for preparing the semiconductor thin film according to claim 10, wherein a material of the first semiconductor thin film is AlN, a material of the second semiconductor thin film is AlScN, and a doping method of a Sc component in the second semiconductor thin film comprises uniform doping, modulation doping or periodic doping.

13. The method for preparing the semiconductor thin film according to claim 1, wherein the substrate comprises a silicon-on-insulator (SOI) substrate, the silicon-on-insulator substrate comprises a supporting layer, a bonding layer and an active silicon layer which are stacked sequentially, and the first groove is disposed in the active silicon layer.

14. The method for preparing the semiconductor thin film according to claim 1, wherein the substrate comprises a Qromis Substrate Technology (QST) engineered substrate, the QST engineered substrate comprises a polycrystalline ceramic core, a barrier layer, a bonding layer and an active silicon layer which are stacked sequentially, and the first groove is disposed in the active silicon layer.

15. The method for preparing the semiconductor thin film according to claim 1, wherein a shape of a horizontal cross-section of the first groove comprises any one of a triangle, a circle, an ellipse, a polygon, a strip shape, or a mesh shape, and the cross-section is parallel to the substrate.

16. The method for preparing the semiconductor thin film according to claim 1, wherein a growth method of the semiconductor thin film comprises an in-situ growth method, an atomic layer deposition method, a chemical vapor deposition method, a molecular beam epitaxial growth method, a plasma enhanced chemical vapor deposition method, a low-pressure chemical evaporation deposition method, a metal organic compound chemical vapor deposition method, or a combination thereof.

17. The method for preparing the semiconductor thin film according to claim 1, wherein a material of the substrate comprises any one of sapphire, silicon or silicon carbide.

18. A semiconductor thin film, wherein the semiconductor thin film is prepared by the method according to claim 1.

19. The semiconductor thin film according to claim 18, wherein the semiconductor thin film is applied to fields of Acoustic Resonator (AR), Light Emitting Diode (LED), High Electron Mobility Transistor (HEMT), High Mobility Diode (HMD), Metal-Oxide-Semiconductor Field Effect Transistor (MOSFET), Ultraviolet Light Emitting Diode (UV-LED), photoelectric detector, hydrogen generator or solar cell.

20. The semiconductor thin film according to claim 18, wherein a material of the semiconductor thin film comprises one of or a combination of AlN, GaN, In, AlScN, AlGaN or AlInGaN.
